(19) United States
(12) Patent Application Publication
(10) Pub. No.: US 2025/0218821 A1
(43) Pub. Date: Jul. 3, 2025

(54) SUBSTRATE PROCESSING APPARATUS

(71) Applicant: SEMES CO., LTD., Cheonan-si (KR)

(72) Inventors: Jong Wha KANG, Seongnam-si (KR); Woo Ram LEE, Seoul (KR); Jae Hoon PARK, Seongnam-si (KR)

(73) Assignee: SEMES CO., LTD., Cheonan-si (KR)

(21) Appl. No.: 18/982,011

(22) Filed: Dec. 16, 2024

(30) Foreign Application Priority Data
Dec. 29, 2023 (KR) 10-2023-0196219

(51) Int. Cl. H01L 21/67; H01L 21/677; H01L 21/687

(52) U.S. Cl. CPC H01L 21/6715; H01L 21/67253; H01L 21/67742; H01L 21/68764

(57) ABSTRACT

Disclosed is an apparatus for treating a substrate, and more particularly, a substrate processing apparatus capable of capturing fumes generated during a substrate treatment without forming vortices in a chamber. The apparatus includes: an outer cup having a treatment space with an open top portion; a support unit for supporting and rotating a substrate in the treatment space; a guide cup disposed in the treatment space, surrounding the support unit, and disposed lower than the substrate supported on the support unit; a liquid supply unit for supplying a treatment solution to the substrate supported on the support unit; an exhaust unit for exhausting the treatment space; and a trap unit for capturing fumes generated during a treatment of the substrate, in which a space between the outer cup and the guide cup is provided as a first exhaust passage for directing airflow in the treatment space to the exhaust unit, and the trap unit is provided in the first exhaust passage, and includes a plurality of rods spaced apart from each other.

### CROSS-REFERENCE TO RELATED APPLICATIONS

This application claims priority to and the benefit of Korean Patent Application No. 10-2023-0196219 filed in the Korean Intellectual Property Office on Dec. 29, 2023, the entire contents of which are incorporated herein by reference.

### TECHNICAL FIELD

The present invention relates to an apparatus for treating a substrate, and more particularly, to a substrate processing apparatus capable of capturing fumes generated during a substrate treatment without forming vortices in a chamber.

### BACKGROUND ART

To manufacture semiconductor devices or flat display panels, various processes, such as deposition, photography, etching, and cleaning, are performed. Among these processes, the photography process includes an application process in which a photosensitizer, such as photoresist, is applied to a surface of a substrate to form a film, an exposure process in which a circuit pattern is transferred to the film formed on the substrate, and a development process in which the film formed on the substrate is selectively removed from the exposed area or the area opposite to the exposed area.

The photoresist used during the application process generates fumes that contain particles during the substrate treatment. The fume needs be properly removed because the fume may contaminate the substrate or device. To remove the fume, a trap ring may be provided in the exhaust path to capture the fume. However, the trap ring reduces the cross-sectional area of the exhaust path and may create airflow stagnation zones. The airflow stagnation zone causes fume backflow, which may contaminate the substrate.

### SUMMARY OF THE INVENTION

The present invention has been made in an effort to provide a substrate processing apparatus capable of removing fumes generated during a substrate treatment.

The present invention has also been made in an effort to provide a substrate processing apparatus capable of preventing reverse airflow in a liquid treating chamber.

The present invention has also been made in an effort to provide a substrate processing apparatus capable of preventing contamination of a substrate due to reverse airflow.

The problem to be solved by the present invention is not limited to the above-mentioned problems, and the problems not mentioned will be clearly understood by those skilled in the art from the descriptions below.

An exemplary embodiment of the present invention provides an apparatus for treating a substrate, the apparatus including: an outer cup having a treatment space with an open top portion; a support unit for supporting and rotating a substrate in the treatment space; a guide cup disposed in the treatment space, surrounding the support unit, and disposed lower than the substrate supported on the support unit; a liquid supply unit for supplying a treatment solution to the substrate supported on the support unit; an exhaust unit for exhausting the treatment space; and a trap unit for capturing fumes generated during a treatment of the substrate, in which a space between the outer cup and the guide cup is provided as a first exhaust passage for directing airflow in the treatment space to the exhaust unit, and the trap unit is provided in the first exhaust passage, and includes a plurality of rods spaced apart from each other.

According to the exemplary embodiment, the plurality of rods may be disposed along a circumferential direction of the substrate supported on the support unit when viewed from above.

According to the exemplary embodiment, the plurality of rods may be provided with a longitudinal direction inclined with respect to a radial direction of the substrate supported on the support unit when viewed from above.

According to the exemplary embodiment, the plurality of rods may be provided with a longitudinal direction inclined downwardly in a direction from the outer cup to the guide cup.

According to the exemplary embodiment, the guide cup may include: an inner wall surrounding the support unit; an outer wall surrounding the inner wall; and a top wall connecting the inner wall and the outer wall, and having an upwardly convex shape, and provide a second exhaust passage surrounded by the outer wall, the inner wall, and the top wall, and the plurality of rods may be installed while penetrating the outer wall and extending to the second exhaust passage.

According to the exemplary embodiment, the exhaust unit may include an exhaust pipe provided in the second exhaust passage.

According to the exemplary embodiment, the plurality of rods may further include: a plurality of first rods provided at the same height as each other and spaced apart from each other; and a plurality of second rods provided at the same height as each other and spaced apart from each other, and the first rod may be disposed at a higher position than the second rod.

According to the exemplary embodiment, the first load and the second load may not overlap when viewed from above.

According to the exemplary embodiment, when viewed from above, a spacing between the plurality of adjacent rods may be wider than a thickness of the rod.

According to the exemplary embodiment, the plurality of rods may be provided to be removably from the guide cup and the outer cup.

According to the exemplary embodiment, the treatment solution may be photoresist.

Another exemplary embodiment of the present invention provides an apparatus for treating a substrate, the apparatus including: an outer cup having a treatment space with an open top portion; a support unit for supporting and rotating a substrate in the treatment space; a guide cup disposed in the treatment space, surrounding the support unit, and disposed lower than the substrate supported on the support unit; a liquid supply unit for supplying photoresist to the substrate supported on the support unit; an exhaust unit for exhausting the treatment space; and a trap unit for capturing fumes generated during a treatment of the substrate, in which a space between the outer cup and the guide cup is provided as a first exhaust passage for directing airflow in the treatment space to the exhaust unit, and a space provided by the guide cup is provided as a second exhaust passage connected with the first exhaust passage, the trap unit includes a plurality of rods spaced apart from each other, and the plurality of rods are provided in any one of the first exhaust passage and the second exhaust passage.

According to the exemplary embodiment, the plurality of rods may be disposed along a circumferential direction of the substrate supported on the support unit when viewed from above, the plurality of rods is provided with a longitudinal direction inclined with respect to a radial direction of the substrate supported on the support unit when viewed from above, and the plurality of rods may be provided with a longitudinal direction inclined downwardly in a direction from the outer cup to the guide cup.

According to the exemplary embodiment, the plurality of rods may further include: a plurality of first rods provided at the same height as each other and spaced apart from each other; and a plurality of second rods provided at the same height as each other and spaced apart from each other, and the first rod is disposed at a higher position than the second rod, and the first load and the second load do not overlap when viewed from above.

According to the exemplary embodiment, when viewed from above, a spacing between the plurality of adjacent rods may be wider than a thickness of the rod.

According to the exemplary embodiment, the plurality of rods may be provided to be removably from the guide cup and the outer cup.

Still another exemplary embodiment of the present invention provides an apparatus for treating a substrate, the apparatus including: an outer cup having a treatment space with an open top portion; a support unit for supporting and rotating a substrate in the treatment space; a guide cup disposed in the treatment space, surrounding the support unit, and disposed lower than the substrate supported on the support unit; a liquid supply unit for supplying photoresist to the substrate supported on the support unit; an exhaust unit for exhausting the treatment space; and a trap unit for capturing fumes generated during a treatment of the substrate, in which a space between the outer cup and the guide cup is provided as a first exhaust passage for directing airflow in the treatment space to the exhaust unit, and the guide cup includes: an inner wall surrounding the support unit; an outer wall surrounding the inner wall; and a top wall connecting the inner wall and the outer wall, and having an upwardly convex shape, and the guide cup provides a second exhaust passage surrounded by the outer wall, the inner wall, and the top wall, the trap unit is provided in the first exhaust passage and the second exhaust passage, and includes a plurality of rods spaced apart from each other, the plurality of rods is disposed along a circumferential direction of the substrate supported on the support unit when viewed from above, and the plurality of rods is provided with a longitudinal direction inclined with respect to a radial direction of the substrate supported on the support unit, and is provided with a longitudinal direction inclined downwardly in a direction from the outer cup to the guide cup, in which a first rod and a second rod do not overlap, and the plurality of rod further includes: a plurality of first rods provided at the same height as each other and spaced apart from each other; and a plurality of second rods provided at the same height as each other and spaced apart from each other, and the first rod is disposed at a higher position than the second rod, and the plurality of rods is installed while penetrating the outer wall and extending to the second exhaust passage, and the exhaust unit includes an exhaust pipe provided in the second exhaust passage.

According to the exemplary embodiment, when viewed from above, a spacing between the plurality of adjacent rods may be wider than a thickness of the rod.

According to the exemplary embodiment, the plurality of rods may be provided to be removably from the guide cup and the outer cup.

According to the exemplary embodiment of the invention, it is possible to remove fumes generated during a substrate treatment.

Further, according to the exemplary embodiment of the present invention, it is possible to prevent airflow in the liquid treating chamber from reversing.

Further, according to the exemplary embodiment of the present invention, it is possible to prevent airflow from reversing and contaminating the substrate.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a perspective view schematically illustrating a substrate processing apparatus according to an exemplary embodiment of the present invention.

FIG. 2 is a front view of the substrate processing apparatus of FIG. 1.

FIG. 3 is a top plan view of an applying block in the substrate processing apparatus of FIG. 1.

FIG. 4 is a top plan view of a developing block in the substrate processing apparatus of FIG. 1.

FIG. 5 is a top plan view schematically illustrating a transfer robot of FIG. 3.

FIG. 6 is a top plan view schematically illustrating one example of a heat treating chamber of FIG. 3 or FIG. 4.

FIG. 7 is a front view of the heat treating chamber of FIG. 6.

FIG. 8 is a cross-sectional view schematically illustrating one example of the liquid treating chamber of FIG. 3 or FIG. 4.

FIG. 9 is an enlarged view of an exhaust passage side of the liquid treating chamber of FIG. 8.

FIG. 10 is a diagram illustrating a trap unit of FIG. 8 viewed from above.

FIG. 11 is a diagram schematically illustrating a substrate processing apparatus according to another exemplary embodiment of the present invention.

FIG. 12 is a diagram schematically illustrating a substrate processing apparatus according to another exemplary embodiment of the present invention.

FIG. 13 is a diagram schematically illustrating a substrate processing apparatus according to another exemplary embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., +10%).

When the terms “about” or “substantially” are used in connection with a numerical value, it should be understood that the associated numerical value includes a manufacturing or operational tolerance (e.g., +10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be processed. However, the technical spirit of the present invention may be applied to devices used for other types of substrate treatment, in addition to wafers.

Hereinafter, exemplary embodiments of the present invention will be described with reference to the accompanying drawings.

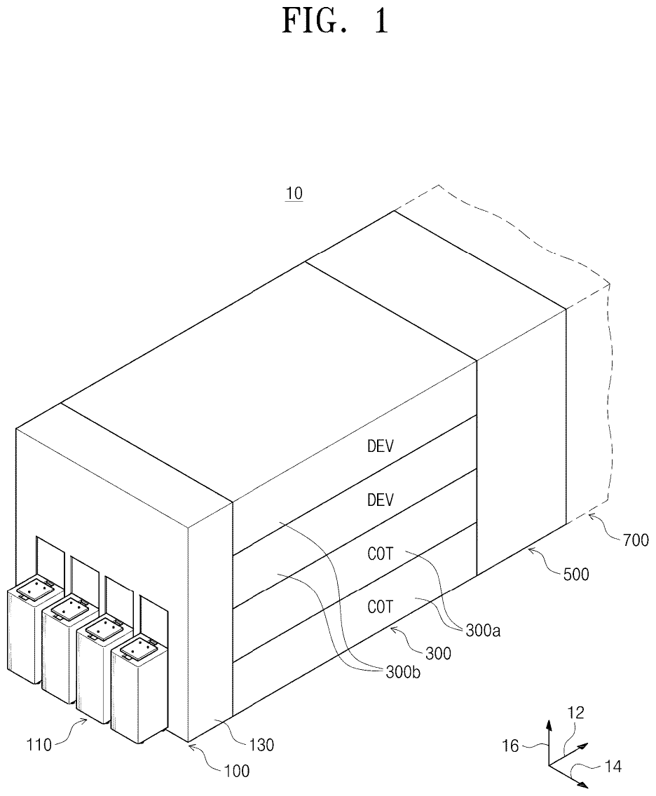

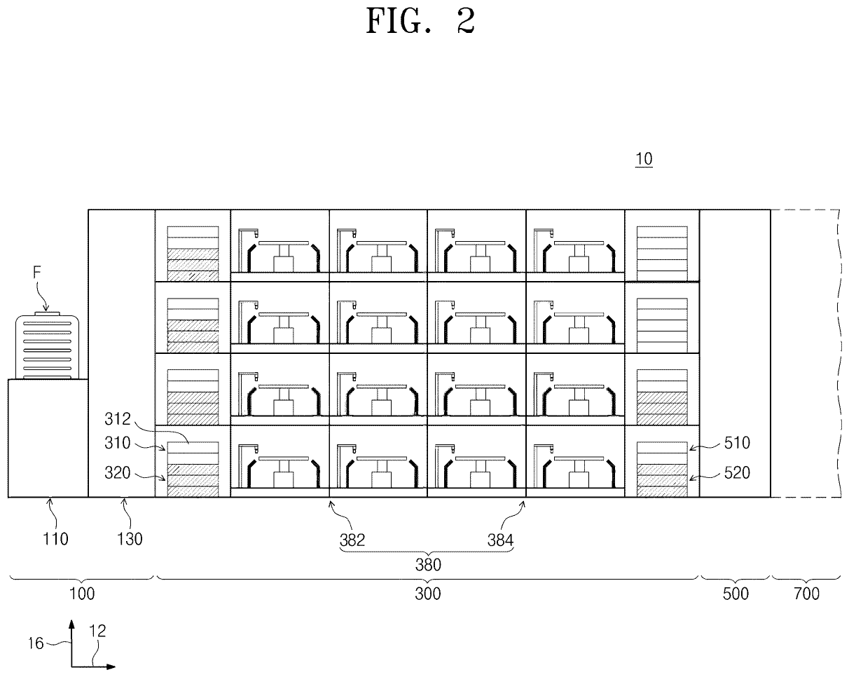

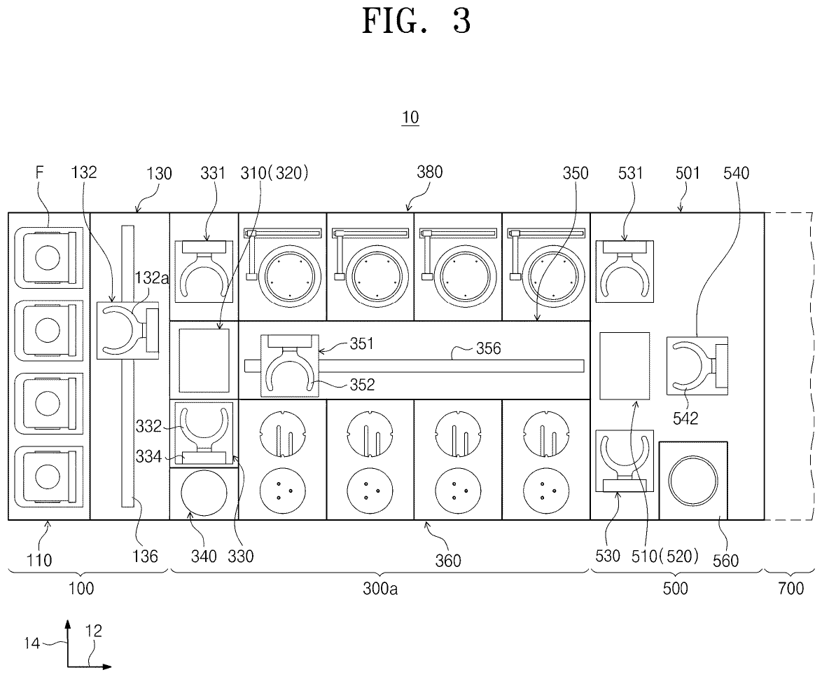

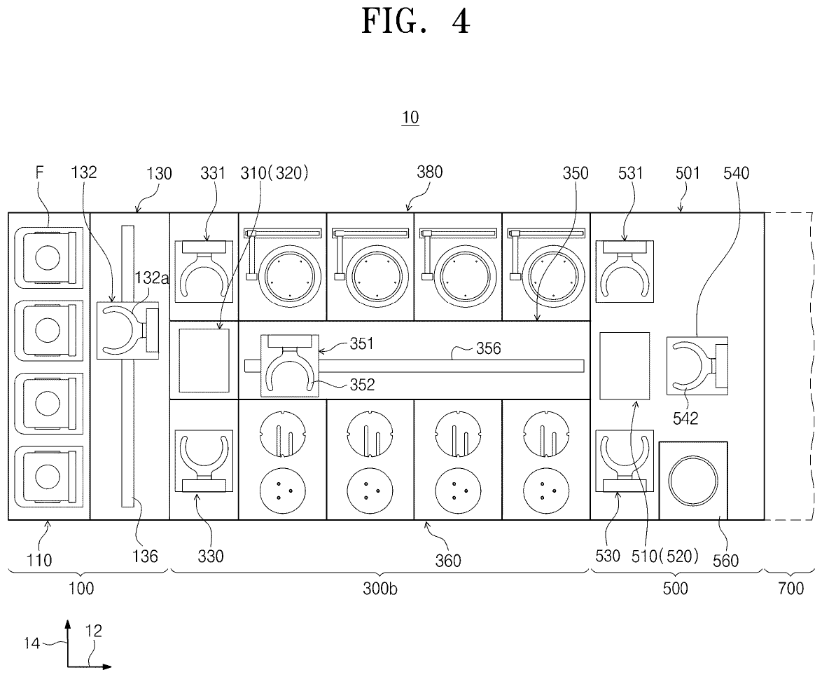

FIG. 1 is a perspective view schematically illustrating a substrate processing apparatus according to an exemplary embodiment of the present invention, and FIG. 2 is a front view of the substrate processing apparatus of FIG. 1. FIG. 3 is a top plan view of an applying block in the substrate processing apparatus of FIG. 1, and FIG. 4 is a top plan view of a developing block in the substrate processing apparatus of FIG. 1.

Referring to FIGS. 1 to 4, a substrate processing apparatus 10 includes an index module 100, a treating module 300, and an interface module 500. According to the exemplary embodiment, the index module 100, the treating module 300, and the interface module 500 are sequentially arranged in a row. Hereinafter, a direction in which the index module 100, the treating module 300, and the interface module 500 are arranged is defined as a first direction 12, a direction perpendicular to the first direction 12 when viewed from above is defined as a second direction 14, and a direction perpendicular to both the first direction 12 and the second direction 14 is defined as a third direction 16.

The index module 100 is provided for transferring a substrate W between a container F in which the substrate W is accommodated and the treating module 300. A longitudinal direction of the index module 100 is provided in the second direction 14. The index module 100 includes a load port 110 and an index frame 130. The container F in which the substrates W are accommodated is placed on the load port 110. The load port 110 is located on the opposite side of the treating module 300 with respect to the index frame 130. A plurality of load ports 110 may be provided, and the plurality of load ports 110 may be disposed along the second direction 14.

In an example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided inside the index frame 130. Within the index frame 130, a guide rail 136 is provided. A longitudinal direction of the guide rail 136 is provided in the second direction 14. The index robot 132 is mounted on the guide rail 136 so as to be movable along the guide rail 136. The index robot 132 includes a hand 132a on which the substrate W is placed. The hand 132a may be provided to be movable forwardly and backwardly, movable linearly along the third direction, and rotatably movable about the axis of the third direction 16.

The interface module 500 connects the treating module 300 with an external exposure device 700. The interface module 500 includes an interface frame 501, a buffer unit 510, a cooling unit 520, a transfer mechanism 530, an interface robot 540, and an additional process chamber 560.

The top end of the interface frame 501 may be provided with a fan filter unit forming a downward airflow therein. The buffer unit 510, the cooling unit 520, the transfer mechanism 530, the interface robot 540, and the additional process chamber 560 are disposed inside the interface frame 501.

The structure and arrangement of the buffer unit 510 and the cooling unit 520 may be the same or similar to those of the buffer unit 310 and the cooling unit 320 provided in the treating module 300. The buffer unit 510 and the cooling unit 520 are disposed adjacent to the end of the transfer chamber 350. The substrate W transferred between the treating module 300, the cooling unit 520, the additional process chamber 560, and the exposure device 700 may temporarily stay in the buffer unit 510. The cooling unit 520 may be provided only at a height corresponding to the application block 300a between the application block 300a and the developing block 300b.

The transfer mechanism 530 may transfer the substrate W between the buffer units 510. The transfer mechanism 530 may also transfer the substrate W between the buffer unit 510 and the cooling unit 520. The transfer mechanism 530 may be provided with the same or similar structure as the transfer mechanism 330 of the treating module 300. Another transfer mechanism 531 may be further provided in a region opposite the region where the transfer mechanism 530 is provided with respect to the buffer unit 510.

The interface robot 540 is disposed between the buffer unit 510 and the exposure device 700. The interface unit 540 is provided to transfer the substrate W between the buffer unit 510, the cooling unit 520, the additional process chamber 560, and the exposure device 700. The interface robot 540 includes a hand 542 on which the substrate W is placed, and the hand 542 may be provided to be movable forwardly and backwardly, rotatable about the third direction 16, and movable along the third direction 16.

The additional process chamber 560 may perform a predetermined additional process before the substrate W processed in the applying block 300a is loaded to the exposure device 700. Optionally, the additional process chamber 560 may perform a predetermined additional process before the substrate W processed in the exposure device 700 is loaded to the developing block 300b. In one example, the additional process may be an edge exposure process that exposes an edge region of the substrate W, or a top surface cleaning process that cleans the top surface of the substrate W, or a bottom surface cleaning process that cleans the bottom surface of the substrate W, or an inspection process that performs a predetermined inspection on the substrate W. A plurality of additional process chambers 560 may be provided, which may be stacked on top of each other.

The treating module 300 performs an application process and a development process on the substrate W. The treating module 300 includes an applying block 300a and a developing block 300b.

The applying block 300a performs an application process on the substrate W before the exposure process. The developing block 300b performs a development process on the substrate W after the exposure process. A plurality of applying blocks 300a is provided. The plurality of applying blocks 300a may be provided while being stacked on top of each other. A plurality of developing blocks 300b is provided. The plurality of developing blocks 300b may be provided to be stacked with each other. In one example, two applying blocks 300a are provided and two developing blocks 300b are provided. The plurality of applying blocks 300a may be located below the developing blocks 300b.

In one example, the plurality of applying blocks 300a may be provided with structures that are identical to each other. A film applied to the substrate W in each of the plurality of applying blocks 300a may be the same type of film. Optionally, the films applied to the substrate W by each applying block 300a may be different types of films. The film applied to the substrate W includes a photoresist film. The film applied to the substrate W may further include an anti-reflective film. Optionally, the film applied to the substrate W may further include a protective film.

Additionally, the two developing blocks 300b may be provided with the same structures as each other. A developer supplied to the substrate W in the plurality of developing blocks 300b may be the same type of liquid. Optionally, the developer supplied to the substrate W may be different types of developer depending on the developing blocks 300b.

Referring to FIG. 3, the applying block 300a includes a buffer unit 310, a cooling unit 320, a hydrophobization chamber 340, a transfer chamber 350, a heat treating chamber 360, and a liquid treating chamber 380.

The buffer unit 310, the cooling unit 320, and the hydrophobization chamber 340 are disposed adjacent to the index block 100. The hydrophobization chamber 340 and the buffer unit 310 may be sequentially disposed along the second direction 14. In addition, the cooling unit 320 and the buffer unit 310 may be provided to be stacked on top of each other in a vertical direction.

The buffer unit 310 includes one or a plurality of buffers 312. When a plurality of buffers 312 is provided, the plurality of buffers 312 may be arranged to be stacked on top of each other. The buffer 312 provides a space for the substrate W to stay when the substrate W is transferred between the index module 100 and the treating module 300. The hydrophobization chamber 340 provides a hydrophobization treatment to the surface of the substrate W. The hydrophobization treatment may be performed prior to performing an application process on the substrate W. The hydrophobization treatment may be accomplished by supplying hydrophobizing gas to the substrate W while heating the substrate W. The cooling unit 320 cools the substrate W. The cooling unit 320 includes one or more cooling plates. When a plurality of cooling plates is provided, the plurality of cooling plates may be arranged to be stacked on top of each other. In one example, the cooling unit 320 may be disposed below the buffer unit 310. The cooling plate may have a flow path through which coolant flows. The substrate W after the hydrophobization treatment may be cooled on the cooling plate.

A transfer mechanism 330 is provided between the hydrophobization chamber 340 and the buffer unit 310 and between the hydrophobization chamber 340 and the cooling unit 320. The transfer mechanism 330 is provided for transferring the substrate W between the buffer unit 310, the hydrophobization chamber 340, and the cooling unit 320.

The transfer mechanism 330 includes a hand 332 on which the substrate W is placed, and the hand 332 may be provided to be movable forwardly and backwardly, rotatable about the third direction 16, and movable along the third direction 16. In one example, the transfer mechanism 330 is moved in the third direction 16 along a guide rail 334. The guide rail 334 extends from an applying block located at the lowest of the applying blocks 300a to a developing block located at the highest of the developing blocks 300b. This allows the transfer mechanism 330 to transfer the substrate W between the blocks 300a and 300b provided on different layers. For example, the transfer mechanism 330 may transfer the substrate W between the applying blocks 300a and 300b provided on different layers. The transfer mechanism 330 may also transfer the substrate W between the applying block 300a and the developing block 300b.

In addition, another transfer unit 331 may be further provided on the opposite side of the side where the hydrophobization chamber 340 is provided with respect to the buffer unit 310. Another transfer unit 331 may be provided to transfer the substrate W between the buffer unit 310 and the cooling unit 320 provided in the same block 300a and 300b. Further, another transfer unit 331 may be provided to transfer the substrate W between the buffer unit 310 and the cooling unit 320 provided in different blocks 300a and 300b.

The transfer chamber 350 is provided so that a longitudinal direction thereof is parallel to the first direction 12. One end of the transfer chamber 350 may be located adjacent to the buffer unit 310 and/or the cooling unit 320. The other end of the transfer chamber 350 may be located adjacent to the interface module 500.

A plurality of heat treating chambers 360 is provided. Some of the heat treating chambers 360 is disposed along the first direction 12. Additionally, some of the heat treating chambers 360 may be stacked along the third direction 16. The heat treating chambers 360 may all be located on one side of the transfer chamber 350.

The liquid treating chamber 380 performs a liquid film formation process to form a liquid film on the substrate W. In one example, the liquid film forming process includes a resist film forming process. The liquid film forming process may include an anti-reflective film forming process. Optionally, the liquid film forming process may further include a protective film forming process. A plurality of liquid treating chambers 380 is provided. The liquid treating chambers 380 may be located on opposite sides of the heat treating chamber 360. For example, all of the liquid treating chambers 380 may be located on the other side of the transfer chamber 350. The liquid treating chambers 380 are arranged side-by-side along the first direction 12. Optionally, some of the liquid treating chambers 1000 may be stacked along the third direction 16.

In one example, the liquid treating chambers 380 include a front end liquid treating chamber 380a and a rear end liquid treating chamber 380b. The front end liquid treating chamber 380a is disposed relatively close to the index module 100, and the rear end liquid treating chamber 380b is disposed further close to the interface module 500.

The front end liquid treating chamber 380a applies a first liquid to the substrate W, and the rear end liquid treating chamber 380b applies a second liquid to the substrate W. The first liquid and the second liquid may be different types of liquid. In one example, the first liquid may be a liquid for forming an anti-reflective film and the second liquid may be a liquid for forming a photoresist film. The photoresist film may be formed on a substrate W to which an anti-reflective film has been applied. Optionally, the first liquid may be a liquid for forming a photoresist film, and the second liquid may be a liquid for forming an antireflective film. In this case, the anti-reflective film may be formed on the substrate W on which the photoresist film is formed. Optionally, the first liquid and the second liquid may be the same kind of liquid, and they may both be liquids for forming the photoresist film.

Referring to FIG. 4, the developing block 300b includes a buffer unit 310, a cooling unit 320, a transfer chamber 350, a heat treating chamber 360, and a liquid treating chamber 380. The arrangement of the buffer unit 310, the cooling unit 320, the transfer chamber 350, the heat treating chamber 360, and the liquid treating chamber 380 in the developing block 300b may be the same as the arrangement of the buffer unit 310, the cooling unit 320, the transfer chamber 350, the heat treating chamber 360, and the liquid treating chamber 380 in the applying block 300a. When viewed from above, the buffer unit 310, the cooling unit 320, the transfer chamber 350, the heat treating chamber 360, and the liquid treating chamber 380 in the developing block 300b and the buffer unit 310, the cooling unit 320, the transfer chamber 350, the heat treating chamber 360, and the liquid treating chamber 380 in the applying block 300 may be disposed in overlapping positions.

The heat treating chamber 360 performs a heating process on the substrate W. The heating process includes a post-exposure baking process performed on the substrate W after the exposure process is completed, and a hard baking process performed on the substrate W after the development process is completed.

The liquid treating chamber performs the development process by supplying a developer onto the substrate W and developing the substrate W.

In FIG. 3 or FIG. 4, the transfer chamber 350 is provided with the transfer robot 351. The transfer robot 351 transfers the substrate W between the buffer unit 310, the cooling unit 320, the heat treating chamber 360, the liquid treating chamber 380, and the buffer unit 510 or the cooling unit 520 of the interface module 500. In one example, the transfer robot 351 includes a hand 352 on which the substrate W is placed. The hand 352 may be provided to be movable forwardly and backwardly, rotatable about the third direction 16, and movable along the third direction 16. A guide rail 356, of which a longitudinal direction is parallel to the first direction 12, is provided within the transfer chamber 350, and the transfer robot 351 may be provided to be movable on the guide rail 356.

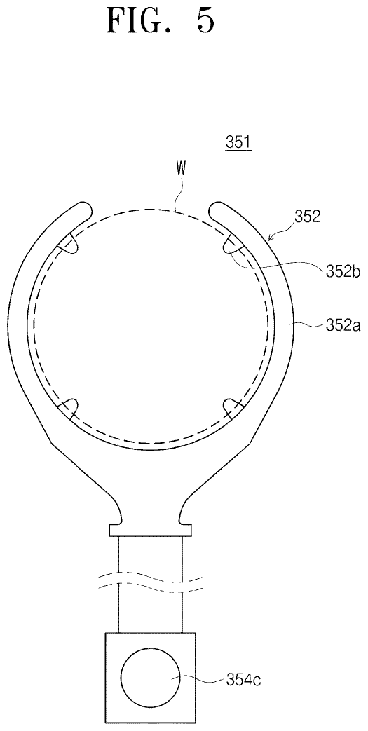

FIG. 5 is a diagram illustrating one example of a hand of the transfer robot. Referring to FIG. 5, the hand 352 includes a base 352a and a support protrusion 352b. The base 352a may have an annular ring shape in which a portion of the circumference is bent. The base 352a has an inner diameter greater than the diameter of the substrate W. The support protrusion 352b extends inwardly from the base 352a. A plurality of support protrusions 352b is provided, and supports an edge region of the substrate W. In one example, support protrusions 352b may be provided in four equally spaced rows.

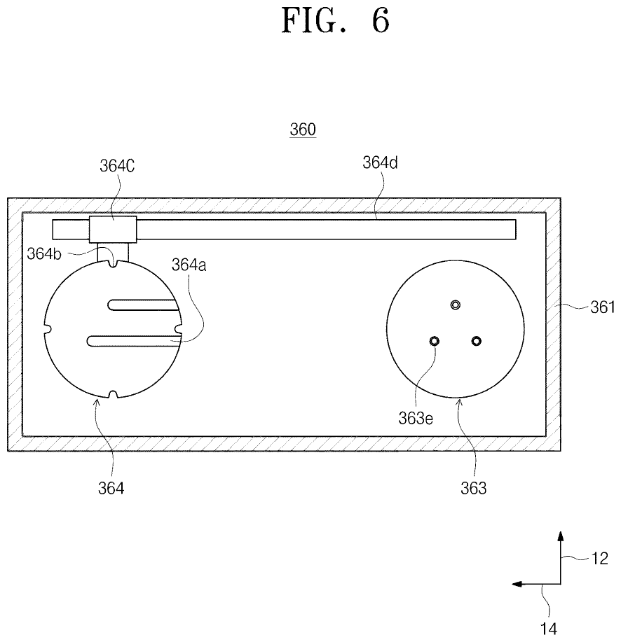

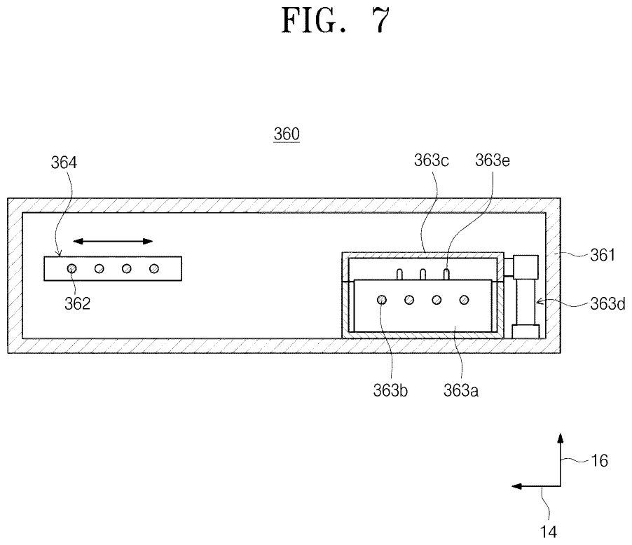

FIG. 6 is a top plan view schematically illustrating an example of the heat treating chamber of FIG. 3 or FIG. 4, and FIG. 7 is a front view of the heat treating chamber of FIG. 6.

Referring to FIGS. 6 and 7, the heat treating chamber 360 includes a housing 361, a heating unit 363, and a transfer plate 364.

The housing 361 is provided in the shape of a generally rectangular parallelepiped. In the lateral wall of the housing 361, an entrance opening (not illustrated) is formed through which the substrate W enters and exits. The entrance opening may remain open. Optionally, a door (not illustrated) may be provided to open and close the entrance opening. The heating unit 363 and the transfer plate 364 are provided within the housing 361.

The heating unit 323 includes a heating plate 363a, a cover 363c, and a heater 323b. The heating plate 363a has a generally circular shape when viewed from above. The heating plate 363a has a larger diameter than the substrate W. The heater 363b is installed on the heating plate 363a. The heater 363b may be provided as a heating wire or heating pattern that is heated by the supply of electrical power. The heating plate 363a is provided with a lift pin 363e. The lift pin 363e is provided to be movable in an up and down direction along the third direction 16. The lift pin 363e receives the substrate W from the transfer robot 352 and places the received substrate W on the heating plate 363a, or lifts the substrate W from the heating plate 363a and hands the substrate over to the transfer robot 352. According to the example, three lift pins 363e may be provided. The cover 363c has a space with an open lower portion therein. The cover 363c is located above the heating plate 363a and is moved in a vertical direction by a driver 363d. The space formed by the cover 363c and the heating plate 363a according to the movement of the cover 363c is provided as a heating space for heating the substrate W.

The transfer plate 364 is provided in a substantially disk shape, and has a diameter corresponding to that of the substrate W. A notch 364b is formed at an edge of the transfer plate 364. The notch 364b may have a shape that corresponds to the protrusion 352b formed on the hands of the transfer robot 352 described above. Further, the notches 364b are provided in a number corresponding to the protrusions 352b formed on the hand, and are formed at locations corresponding to the protrusions 352b. In a position in which the hand and the transfer plate 364 are arranged in the vertical direction, the substrate W is transferred between the hand 354 and the transfer plate 364 when the vertical position of the hand and the transfer plate 364 is changed. The transfer plate 364 is mounted on a guide rail 364d, and may be movable along the guide rail 364d by the driver 364c.

A plurality of slit-shaped guide grooves 364a is provided in the transfer plate 364. The guide grooves 364a extend from a distal end of the transfer plate 364 to an interior of the transfer plate 364. The longitudinal direction of the guide groove 364a is provided along the second direction 14, and the guide grooves 364a are spaced apart from each other along the first direction 12. The guide groove 364a prevents the transfer plate 364 and lift pins 363e from interfering with each other when the substrate W is transferred between the transfer plate 364 and the heating unit 363.

The transfer plate 364 is provided of a thermally conductive material. In one example, the transfer plate 364 may be provided from a metal material.

A cooling flow path 364 is formed in the transfer plate 364. The cooling flow path 364 is supplied with coolant. The substrate W, which has been completely heated in the heating unit 363, may be cooled while being transferred by the transfer plate 364. Also, the substrate W may be cooled on the transfer plate 364 while the transfer plate 364 is stopped for the substrate W to be taken over by the transfer robot 351.

Optionally, a cooling unit may be further provided within the housing 361. In this case, the cooling unit may be arranged in parallel with the heating unit 363. The cooling unit may be provided as a cooling plate having a passage formed therein through which coolant flows. The substrate that has been heated in the heating unit may be returned to the cooling unit for cooling.

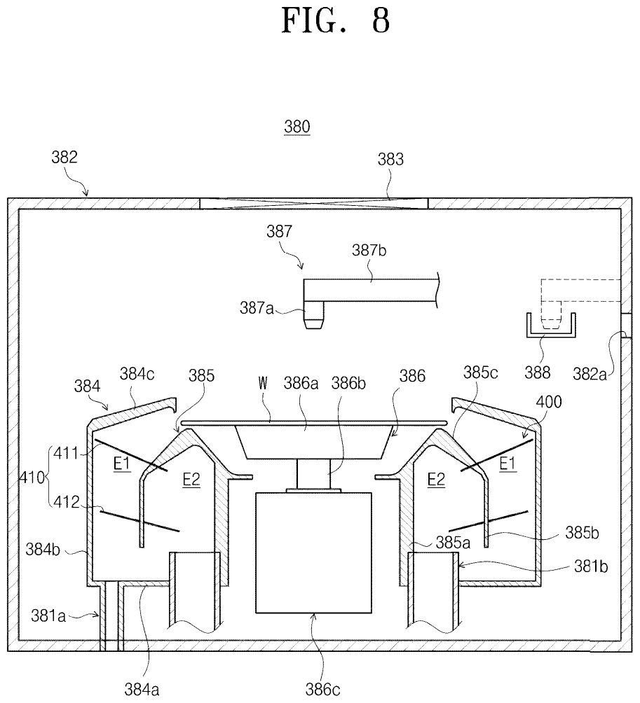

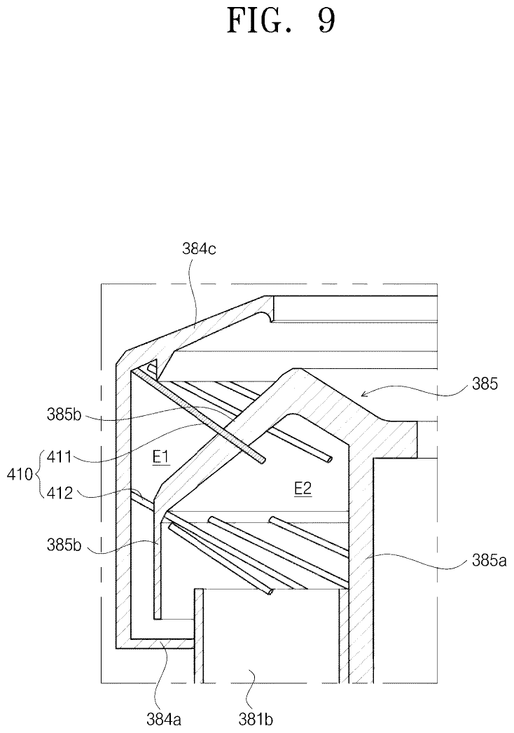

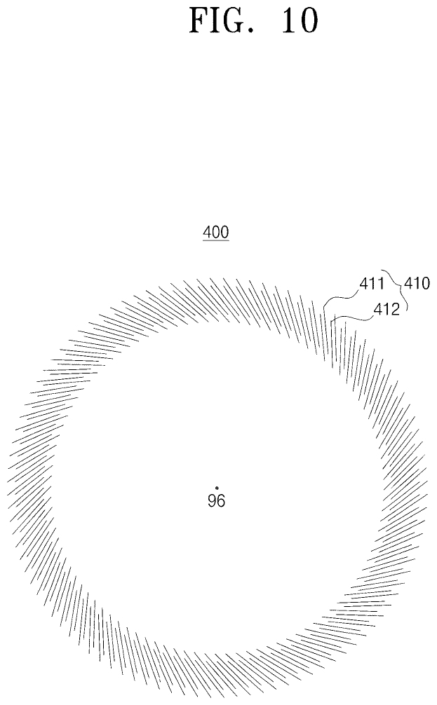

FIG. 8 is a cross-sectional view schematically illustrating one example of the liquid treating chamber of FIG. 3 or FIG. 4, FIG. 9 is an enlarged view of an exhaust passage side of the liquid treating chamber of FIG. 8, and FIG. 10 is a diagram illustrating a trap unit of FIG. 8 viewed from above.

Referring to FIGS. 8 to 10, the liquid treating chamber 380 includes a housing 382, an outer cup 384, a support unit 386, a liquid supply unit 387, an exhaust unit 388, and a trap unit 400.

The housing 382 is provided in a rectangular cylindrical shape having an interior space. An opening 382a is formed in one side of the housing 382. The opening 382a functions as a passage through which the substrate W enters and exits. A door (not illustrated) is installed in the opening 382a, and the door opens and closes the opening.

An inner space of the housing 382 is provided with the outer cup 384. The outer cup 384 has a treatment space with an open top.

The support unit 386 supports the substrate W within the treatment space of the outer cup 384. The support unit 386 includes has a support plate 386a, a rotation shaft 386b, and a driver 386c. The support plate 386a is provided with a circular top surface. The support plate 386a has a diameter smaller than the substrate W. The support plate 386a is provided to support the substrate W by vacuum pressure. The rotation shaft 386b is coupled to the center of the lower surface of the support plate 386a, and the driver 386c is provided on the rotation shaft 386b to provide rotational force to the rotation shaft 386b. The driver 386c may be a motor. Additionally, a lifting driver (not illustrated) may be provided to adjust the relative height of the support plate 386a and the outer cup 384.

The liquid supply unit 387 supplies the treatment solution onto the substrate W. When the liquid treating chamber 380 is provided in the applying block 300a, the treatment solution may be a liquid for forming a photoresist film, an anti-reflective film, or a protective film. When the liquid treating chamber 380 is provided in the developing block 300b, the treatment solution may be a developer liquid. The liquid supply unit 387 has a nozzle 387a, a nozzle support 387b, and a liquid supply source (not illustrated). The nozzle 387a discharges the treatment solution onto the substrate W. The nozzle 387a is supported on a nozzle support 387b. The nozzle support 387b moves the nozzle 387a between a process position and a standby position. In the process position, the nozzle 387a supplies the treatment solution to the substrate W placed on the support plate 386a, and after completing the supply of the treatment solution, the nozzle 387a waits in the standby position. In the standby position, the nozzle 387a waits at a groove port 388, the groove port 388 is located on the outside of the outer cup 384 within the housing 382.

On the top wall of the housing 382, a fan filter unit 383 is disposed to supply a downward airflow to the inner space. The fan filter unit 383 includes a fan that introduces air from the outside into the inner space and a filter that filters the air from the outside.

The outer cup 384 includes a bottom wall 384a, a lateral wall 384b, and a top wall 384c. The inner portion of the outer cup 384 is provided as the inner space described above. The inner space includes a treatment space at the top and an exhaust space at the bottom.

The bottom wall 384a is provided in a circular shape and has an opening in the center. The lateral wall 384b extends upwardly from the outer end of the bottom wall 384a. The lateral wall 384b is provided in a ring shape and is provided vertical to the bottom wall 384a. In one example, the lateral wall 384b extends to a height equal to the top surface of the support plate 386a, or extends to a height slightly lower than the top surface of the support plate 386a. The top wall 384c has a ring shape, with an opening in the center. The top wall 384c is provided with an upward slope from the top end of the lateral wall 384b toward the center axis of the outer cup 384.

The guide cup 385 is located on the inner side of the outer cup 384. The guide cup 385 has an inner wall 385a, an outer wall 385b, and a top wall 385c. The inner wall 385a has a through-hole that is perforated in the vertical direction. The inner wall 385a is arranged to surround the driver 386c. The inner wall 385a minimizes the exposure of the driver 386c to the airflow 84 in the treatment space. The rotational shaft 386b and/or the driver 386c of the support unit 386 extend in the vertical direction through the through-hole. The outer wall 385b is spaced apart from the inner wall 385a and is disposed to surround the inner wall 385a. The outer wall 385b is spaced apart from the lateral wall 384b of the outer cup 384. The inner wall 385a is spaced upwardly from the bottom wall 384a of the outer cup 384. The top wall 385c connects the upper end of the outer wall 385b with the upper end of the inner wall 385a. The top wall 385c has a ring shape and is disposed to surround the support plate 386a. In one example, the top wall 385c has an upwardly convex shape.

The bottom wall 384a of the outer cup 384 is connected to an outlet pipe 381a for discharging the treatment solution and an outlet pipe 381b. The outlet pipe 381a may be connected to the outer cup 384 from the outer side of the outer wall 385b when viewed from above. The outlet pipe 381a may be connected to the outer cup 384 from the outer side of the outer wall 385b when viewed from above.

The space below the support plate 386a in the treatment space may be provided as an exhaust passage. The exhaust passage includes a first exhaust passage E1 and a second exhaust passage E2. Gas in the treatment space may be exhausted through the first exhaust passage E1 and the second exhaust passage E2 sequentially.

The first exhaust passage E1 may be defined by the outer cup 384 and the guide cup 385. In one example, the first exhaust passage E1 may be provided with a space surrounded by the lateral wall 384b, the top wall 384c, the outer wall 385b, the top wall 385c, and/or a space below the surrounded space as an exhaust space.

The second exhaust passage E2 may be defined by the guide cup 385. In one example, the second exhaust passage E2 may be provided with a space surrounded by the inner wall 385a, the outer wall 385b, and the top wall 385c and/or a space beneath the surrounded space as an exhaust space.

An exhaust unit 388 evacuates the interior of the outer cup 384 and the guide cup 385. The exhaust unit 388 includes an exhaust pipe 388a. The exhaust pipe 388a is connected to the bottom wall 384a. The exhaust pipe 388a penetrates the bottom wall 384a and is connected to the second exhaust passage E2.

The trap unit 400 captures fumes generated during the treatment of the substrate W. The trap unit 400 may be provided in the first exhaust passage E1 and the second exhaust passage E2. The trap unit 400 includes a plurality of rods 410.

The plurality of rods 410 are spaced apart from each other. The plurality of rods 410 may be disposed along a circumferential direction of the substrate W supported on the support unit 386 when viewed from above. The plurality of rods 410 may be provided such that their longitudinal direction is inclined with respect to a radial direction of the substrate W supported on the support unit 386. The plurality of rods 410 may be provided sloping downwardly from the outer cup 384 toward the guide cup 385. The plurality of rods 410 may be removably provided. The plurality of rods 410 includes a plurality of first rods 411 and a plurality of second rods 412. When viewed from above, the spacing between the plurality of neighboring rods 410 may be provided wider than the thickness of the rod 410.

The plurality of first rods 411 are installed in the first exhaust passage E1. The plurality of first rods 411 are provided at the same height as each other and are spaced apart from each other. The plurality of first rods 411 may be provided in a shape extending from the lateral wall 384b to the top wall 385c. The plurality of first rods 411 may also be provided in a shape penetrating the top wall 385c and extending to the second exhaust passage E2.

The plurality of second rods 412 are installed in the second exhaust passage E2. The plurality of second rods 412 are provided at the same height as each other and are spaced apart from each other. The plurality of second rods 412 may be provided in a shape extending from the outer wall 385b to the second exhaust passage E2. The plurality of second rods 412 may also be provided in a shape penetrating the outer wall 385b and extending to the first exhaust passage E1.

The first rod 411 may be disposed at a higher position than the second rod 412. When viewed from above, the first rod 411 and the second rod 412 may be provided so as not to overlap.

According to the exemplary embodiment of the present invention, fumes may be captured by the plurality of rods 410 provided in the exhaust passages. Since the plurality of rods 410 are provided in the first exhaust passage E1 and the second exhaust passage E2, fume leakage may be minimized. Furthermore, the shape of the rod minimizes the impact on the cross-sectional area of the exhaust passage, which minimizes the reverse airflow or vortices. As a result, fume backflow and contamination of the substrate W may be minimized.

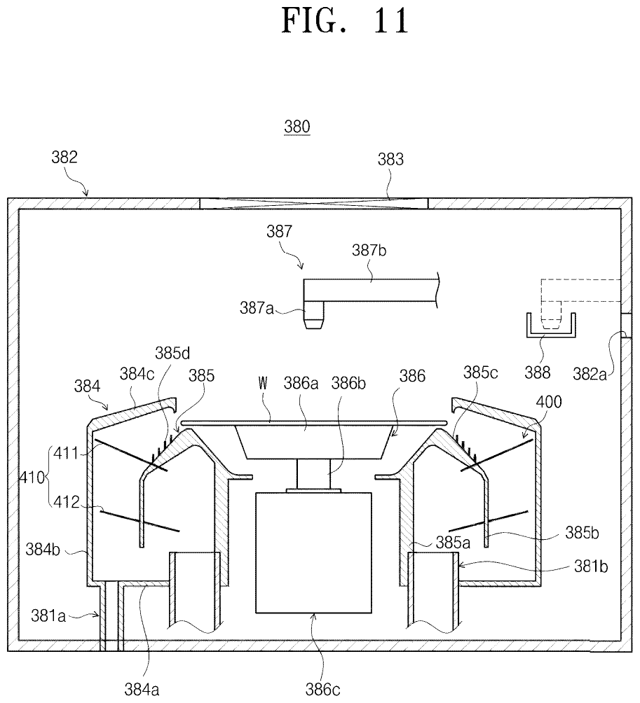

In the example described above, the present invention has been described based on the case where no separate structure is provided on the upper surface of the top wall 385c as an example. However, the present invention is not limited to this, and a plurality of ring-shaped protrusions 385d may be provided on the upper surface of the top wall 385c, as illustrated in FIG. 11.

Furthermore, in the example described above, the present invention has been described based on the case where a gas-liquid separation plate 389 is not provided on the bottom wall 384a of the outer cup as an example. However, the present invention is not limited thereto, and the gas-liquid separation plate 389 may be provided on the bottom wall 384a. The gas-liquid separation plate 389 may be provided to extend upwardly from the bottom wall 384a of the outer cup 384. The gas-liquid separation plate 1230 may be provided in a ring shape. The gas-liquid separation plate 389 may be located between the lateral wall 384b of the outer cup 384 and the outer wall 385b of the guide cup 385 when viewed from above. The top end of the gas-liquid separation plate 389 may be located lower than the bottom end of the outer wall 385b of the guide cup 385. When the gas-liquid separation plate 389 overlaps the plurality of rods 410, the plurality of rods 410 may penetrate the gas-liquid separation plate 389.

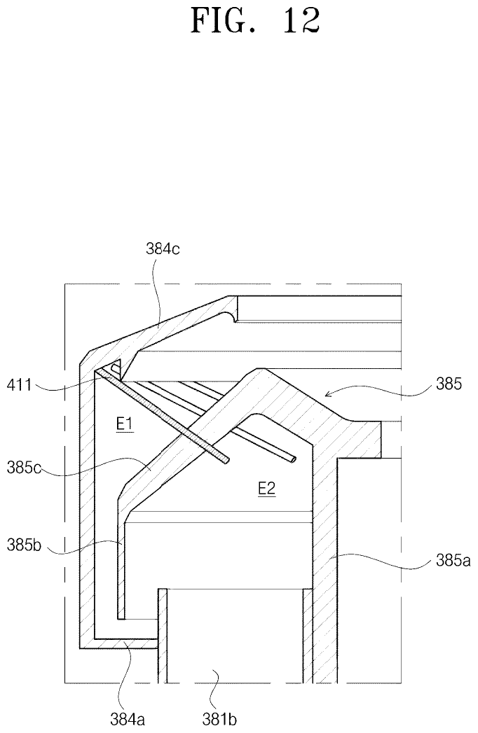

Further, in the examples described above, the present invention has been described based on the case where both the first rod 411 and the second rod 412 are provided as an example. However, the present invention is not limited thereto, and only the first rod 411 may be provided, as illustrated in FIG. 12.

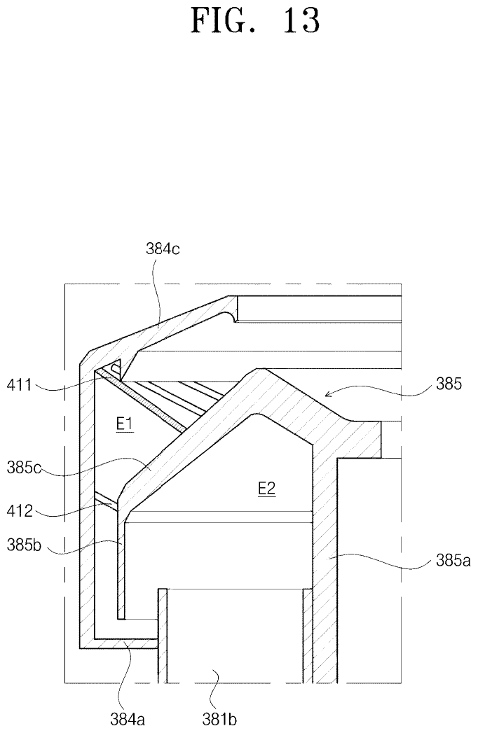

Furthermore, in the example described above, the present invention has been described based on the case where both the first rod 411 and the second rod 412 are provided in the first exhaust passage E1 and the second exhaust passage E2 while being installed through the top wall 385c as an example. However, the present invention is not limited thereto, and both the first rod 411 and the second rod 412 may be provided in the first exhaust passage E1 only, as illustrated in FIG. 13.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

What is claimed is:

1. An apparatus of processing a substrate, the apparatus comprising:
an outer cup having a treatment space with an open top portion;
a support unit for supporting and rotating a substrate in the treatment space;
a guide cup disposed in the treatment space, surrounding the support unit, and disposed lower than the substrate supported on the support unit;
a liquid supply unit for supplying a treatment solution to the substrate supported on the support unit;
an exhaust unit for exhausting the treatment space; and
a trap unit for capturing fumes generated during a treatment of the substrate,
wherein a space between the outer cup and the guide cup is provided as a first exhaust passage for directing airflow in the treatment space to the exhaust unit, and
the trap unit is provided in the first exhaust passage, and includes a plurality of rods spaced apart from each other.

2. The apparatus of claim 1, wherein the plurality of rods is disposed along a circumferential direction of the substrate supported on the support unit when viewed from above.

3. The apparatus of claim 1, wherein the plurality of rods is provided with a longitudinal direction inclined with respect to a radial direction of the substrate supported on the support unit when viewed from above.

4. The apparatus of claim 1, wherein the plurality of rods is provided with a longitudinal direction inclined downwardly in a direction from the outer cup to the guide cup.

5. The apparatus of claim 1, wherein the guide cup includes:
an inner wall surrounding the support unit;
an outer wall surrounding the inner wall; and
a top wall connecting the inner wall and the outer wall, and having an upwardly convex shape, and provides a second exhaust passage surrounded by the outer wall, the inner wall, and the top wall.

6. The apparatus of claim 5, wherein the plurality of rods is installed while penetrating the outer wall and extending to the second exhaust passage.

7. The apparatus of claim 6, wherein the exhaust unit includes an exhaust pipe provided in the second exhaust passage.

8. The apparatus of claim 2, wherein the plurality of rods further includes:
a plurality of first rods provided at the same height as each other and spaced apart from each other; and
a plurality of second rods provided at the same height as each other and spaced apart from each other, and
the first rod is disposed at a higher position than the second rod.

9. The apparatus of claim 8, wherein the first load and the second load do not overlap when viewed from above.

10. The apparatus of claim 1, wherein when viewed from above, a spacing between the plurality of adjacent rods is wider than a thickness of the rod.

11. The apparatus of claim 1, wherein the plurality of rods is provided to be removably from the guide cup and the outer cup.

12. The apparatus of claim 1, wherein the treatment solution is photoresist.

13. An apparatus of processing a substrate, the apparatus comprising:
an outer cup having a treatment space with an open top portion;
a support unit for supporting and rotating a substrate in the treatment space;
a guide cup disposed in the treatment space, surrounding the support unit, and disposed lower than the substrate supported on the support unit;
a liquid supply unit for supplying photoresist to the substrate supported on the support unit;
an exhaust unit for exhausting the treatment space; and
a trap unit for capturing fumes generated during a treatment of the substrate,
wherein a space between the outer cup and the guide cup is provided as a first exhaust passage for directing airflow in the treatment space to the exhaust unit, and
a space provided by the guide cup is provided as a second exhaust passage connected with the first exhaust passage,
the trap unit includes a plurality of rods spaced apart from each other, and
the plurality of rods are provided in any one of the first exhaust passage and the second exhaust passage.

14. The apparatus of claim 13, wherein the plurality of rods is disposed along a circumferential direction of the substrate supported on the support unit when viewed from above,
the plurality of rods is provided with a longitudinal direction inclined with respect to a radial direction of the substrate supported on the support unit when viewed from above, and
the plurality of rods is provided with a longitudinal direction inclined downwardly in a direction from the outer cup to the guide cup.

15. The apparatus of claim 13, wherein the plurality of rods further includes:
a plurality of first rods provided at the same height as each other and spaced apart from each other; and
a plurality of second rods provided at the same height as each other and spaced apart from each other, and
the first rod is disposed at a higher position than the second rod, and
the first load and the second load do not overlap when viewed from above.

16. The apparatus of claim 15, wherein when viewed from above, a spacing between the plurality of adjacent rods is wider than a thickness of the rod.

17. The apparatus of claim 13, wherein the plurality of rods is provided to be removably from the guide cup and the outer cup.

18. An apparatus of processing a substrate, the apparatus comprising:
an outer cup having a treatment space with an open top portion;
a support unit for supporting and rotating a substrate in the treatment space;
a guide cup disposed in the treatment space, surrounding the support unit, and disposed lower than the substrate supported on the support unit;
a liquid supply unit for supplying photoresist to the substrate supported on the support unit;
an exhaust unit for exhausting the treatment space; and
a trap unit for capturing fumes generated during a treatment of the substrate,
wherein a space between the outer cup and the guide cup is provided as a first exhaust passage for directing airflow in the treatment space to the exhaust unit, and
the guide cup includes:
an inner wall surrounding the support unit;
an outer wall surrounding the inner wall; and
a top wall connecting the inner wall and the outer wall, and having an upwardly convex shape, and
the guide cup provides a second exhaust passage surrounded by the outer wall, the inner wall, and the top wall,
the trap unit is provided in the first exhaust passage and the second exhaust passage, and includes a plurality of rods spaced apart from each other,
the plurality of rods is disposed along a circumferential direction of the substrate supported on the support unit when viewed from above, and
the plurality of rods is provided with a longitudinal direction inclined with respect to a radial direction of the substrate supported on the support unit, and is provided with a longitudinal direction inclined downwardly in a direction from the outer cup to the guide cup,
the plurality of rod further includes:
a plurality of first rods provided at the same height as each other and spaced apart from each other; and
a plurality of second rods provided at the same height as each other and spaced apart from each other, and
the first rod is disposed at a higher position than the second rod, and
the first load and the second load do not overlap when viewed from above, and
the plurality of rods is installed while penetrating the outer wall and extending to the second exhaust passage, and
the exhaust unit includes an exhaust pipe provided in the second exhaust passage.

19. The apparatus of claim 18, wherein when viewed from above, a spacing between the plurality of adjacent rods is wider than a thickness of the rod.

20. The apparatus of claim 18, wherein the plurality of rods is provided to be removably from the guide cup and the outer cup.
